(19) United States
(12) Patent Application Publication
(10) Pub. No.: US 2013/0284731 A1
(43) Pub. Date: Oct. 31, 2013

(54) Collapsible Protective Apparatus

(71) Applicant: Endress + Hauser Conducta Gesellschaft fur Mess- Und Regeltechnik mbH + Co. KG, (US)

(72) Inventor: Axel Vierkotter, Rutesheim (DE)

(21) Appl. No.: 13/854,609

(22) Filed: Apr. 1, 2013

(30) Foreign Application Priority Data
Apr. 3, 2012 (DE) 102012102889.3

(51) Int. Cl. H05K 5/00

(52) U.S. Cl. CPC H05K 5/0013
USPC 220/4.02

(57) ABSTRACT

A collapsible, protective apparatus for protecting an object against weather related influences and comprises an element having a plurality of interconnected segments, including at least one rear wall segment, a roof segment, a first side wall segment and a second side wall segment, wherein the segments are connected to one another via at least three bendable transition regions, wherein the transition regions are located between the roof segment and the rear wall segment and between the first side wall segment and the rear wall segment and between the second side wall segment and the rear wall segment, and wherein the individual segments can be formed from a planar, spread mode with the assistance of the transition regions into a three-dimensional structure.

The invention relates to a collapsible, protective apparatus for protecting an object, for example, a field device of automation technology, against weather related influences and to a system composed of a collapsible protective apparatus and such a field device.

In automation technology, especially in process automation technology and manufacturing-automation technology, field devices are often applied, which serve for registering and/or influencing process variables. Serving for registering process variables are sensors, such as, for example, fill level measuring devices, flow measuring devices, pressure- and temperature measuring devices, pH-redox potential measuring devices, conductivity measuring devices, etc., which register the corresponding process variables, fill level, flow, pressure, temperature, pH-value, or conductivity. Serving for influencing process variables are actuators, such as, for example, valves or pumps, via which the flow of a liquid in a section of pipeline, or the fill level in a container, can be changed. Referred to as field devices are, in principle, all devices, which are applied near to the process and deliver, or process, process-relevant information. Thus, in connection with the invention, the terminology ‘field devices’ includes also remote I/Os, radio adapters, or, generally, devices, which are arranged at the field level. A large number of such field devices are produced and available from the firm, Endress + Hauser.

Known from the state of the art are already a large number of protective apparatuses, or protective covers, for field devices for protection against solar radiation, fouling, weather influences, etc. These apparatuses, or protective covers, known from the state of the art protective have, however, the disadvantage that they are not collapsible and, thus, especially in the case of transport or storage, take up a large amount of space. Furthermore, these protective apparatuses, or protective covers, are so embodied that their mounting requires extra tools, such as, for example, a wrench, screw driver, etc.

A goal of the invention is to optimize/improve user friendliness of an apparatus for protecting an object, as well as a system composed of the apparatus for protecting an object and a field device of automation technology as the object.

The goal is achieved relative to the apparatus by features including that the apparatus is a collapsible, protective apparatus for protecting an object against weather related influences. The apparatus is formed of an element having a plurality of interconnected segments and includes at least one rear wall segment, a roof segment, a first side wall segment and a second side wall segment. For this, the segments are connected to one another via at least three bendable transition regions and the transition regions are located between the roof segment and the rear wall segment and between the first side wall segment and the rear wall segment and between the second side wall segment and the rear wall segment and the individual segments can thus be formed from a planar, spread mode with the assistance of the transition regions into a three-dimensional structure.

The goal is achieved relative to the apparatus, furthermore, by features including that the apparatus can be a collapsible, protective apparatus for protecting an object against weather related influences. The apparatus is embodied by a plurality of individual segments and includes at least one rear wall segment, a roof segment, a first side wall segment and a second side wall segment. To accomplish this, the rear wall segment, the roof segment, the first side wall segment and the second side wall segment have securement means, so that the individual segments can be connected from a planar, spread mode by shape interlocking of the securement means into a three-dimensional structure.

The collapsible, protective apparatus of the invention is injection molded or cast, preferably of synthetic material (e.g. plastic), essentially in a planar, spread mode.

The manufacturing technology, respectively manufacturing methods, of plastic injection molding or also casting permit(s) the molding of complex forms in all directions. Thus, especially transition regions, such as, for example, hinges, can be formed, and, moreover, also structures, which have complex three-dimensional shapes.

According to the invention, the user friendliness of the apparatus is optimized, or increased, by reducing the volume, respectively the transport volume, by collapsing the protective apparatus. For this, the collapsible, protective apparatus is embodied in such a manner that it is implemented either from an element having a plurality of interconnected segments with transition regions or from a plurality of connectable, individual segments having corresponding securing means. In this way, the collapsible, protective apparatus can be formed, or connected, from a planar, spread mode, in which it is, for example, cost effectively transportable as well as storable, into a three-dimensional structure, in which it also serves for protecting an object from weather related influences. The user friendliness of the system is optimized by features including that the mounting of the collapsible, protective apparatus on the object to be protected, for example, a field device of automation technology, can be performed without tools.

An advantageous embodiment of the apparatus of the invention provides that at least one of the segments has, in each case, at least one spacing apparatus, wherein the at least one spacing apparatus is arranged in such a manner on the, in each case, corresponding segment that it can be set up from the plane of the segment. This offers the advantage that the transport volume of the collapsible, protective apparatus essentially does not increase and, thus, the protective apparatus can always still be cost effectively transported and stored.

An advantageous embodiment of the apparatus of the invention provides that the transition regions are implemented as hinges. This offers advantages especially in the manufacture of the collapsible, protective apparatus.

A favorable embodiment of the apparatus of the invention provides that the roof segment has at least one snap fit mechanism and on the first side segment and the second side segment, in each case, there is provided at least a first means for engaging with the snap fit mechanism of the roof segment. This offers the advantage that the stability of the protective apparatus formed with the assistance of the transition regions to a three-dimensional structure is supplementally protected against unintended deformation.

Another advantageous embodiment of the apparatus of the invention provides that the securement means is embodied in such a manner that the roof segment, the rear wall segment, the first side wall segment and the second side wall segment can be connected to form the three-dimensional structure.

In an additional embodiment of the apparatus of the invention, it is provided that the rear wall segment has at least one securement mechanism, with the assistance of which the collapsible, protective apparatus is secured to the object to be protected.

Another advantageous embodiment of the apparatus of the invention provides that one of the two side segments has a latch connected via a flexible joint, wherein a second means is provided on the latch for releasable clipping to the other side segment.

Another advantageous embodiment of the apparatus of the invention provides that the side segment, to which the latch is clipped, has a clip counterpart, which receives the second means for releasable clipping of the latch. This offers the advantage that the collapsible, protective apparatus is affixable, respectively releasable, by the user, or operator, with the assistance of the latch. Thus, the protective apparatus is especially user friendly, in that it can, on the one hand, be secured against unintended slipping, or springing, off, and, on the other hand, it can be rapidly released, in order, for example, to make a type label lying therebeneath accessible.

Another advantageous embodiment of the apparatus of the invention provides that the latch is so embodied that, in the clipped state, it protrudes beyond the side, to which it is clipped, in such a manner that a gripping element forms for releasing the latch.

The object is achieved relative to the system by features including that the system is composed of at least one protective apparatus, as such is described in one or more of the above paragraphs, and at least one object to be protected, wherein the object to be protected is a field device of automation technology and the collapsible, protective apparatus is placed on the field device of automation technology.

Another advantageous embodiment of the system of the invention provides that the field device is affixed at a location of installation via at least one securement element, wherein the securement mechanism of the protective apparatus has at least one cutout, wherein the cutout is located on the rear wall segment in such a manner that, in the case of placing the protective apparatus on the field device, the cutout receives the at least one securement element of the field device, and wherein the collapsible, protective apparatus is affixed on the field device in such a manner, that an unintended slipping off is prevented. This offers the advantage that the collapsible, protective apparatus can be slipped on with accurate fit and, thus, in an especially user friendly manner, onto the field device already affixed at the location of installation, without requiring that, for example, the field device must first be removed. Moreover, the system is distinguished by the fact that, in this way, no further tool is required for mounting the collapsible, protective apparatus on the field device.

Another advantageous embodiment of the system of the invention provides that the latch of the collapsible, protective apparatus tightens, with the assistance of the housing floor of the field device, in such a manner that removal of the protective apparatus without a preceding releasing of the clip counterpart is prevented.

Another advantageous embodiment of the system of the invention provides that the at least one spacing apparatus is embodied in such a manner that the collapsible, protective apparatus is so positionable on the field device that an air gap forms between the side segments as well as the roof segment of the protective apparatus and the side regions as well as the top of the housing of the field device. This form of embodiment of the spacing apparatus offers the advantage that, through the air gap, heat given off during operation of the field device can be removed.

Another advantageous embodiment of the system of the invention provides that the roof segment and the two side segments are so embodied that the roof segment and the two side segments protrude frontally over the field device and the side segments terminate essentially flushly with the roof segment and, thus, form a protrusion. This offers the advantage that the protrusion provides sun protection, which enables an operator, or user, to read the display of the field device easily, even in the presence of solar radiation.

The invention will now be explained in greater detail based on the appended drawing, the figures of which show as follows:

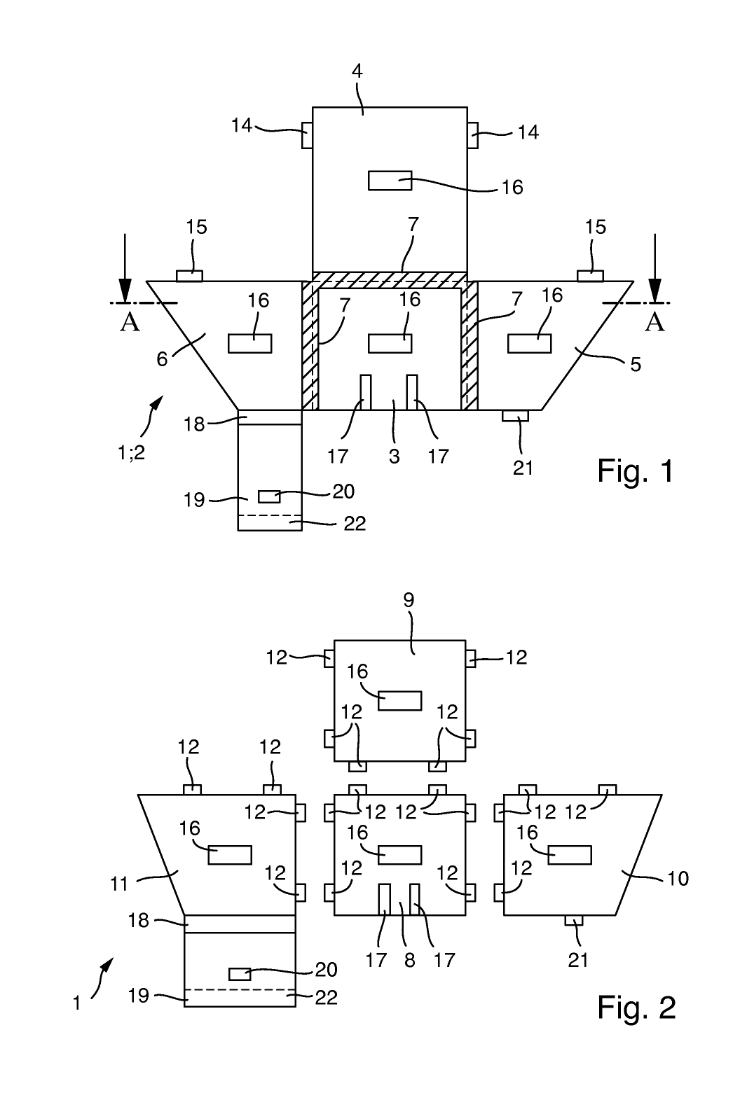

FIG. 1 a plan view of an embodiment of the collapsible, protective apparatus of the invention embodied in the form of an element having a plurality of interconnected segments in the planar, spread mode,

FIG. 2 a plan view of an embodiment of the collapsible, protective apparatus of the invention embodied in the form of a plurality of individual segments in the planar, spread mode,

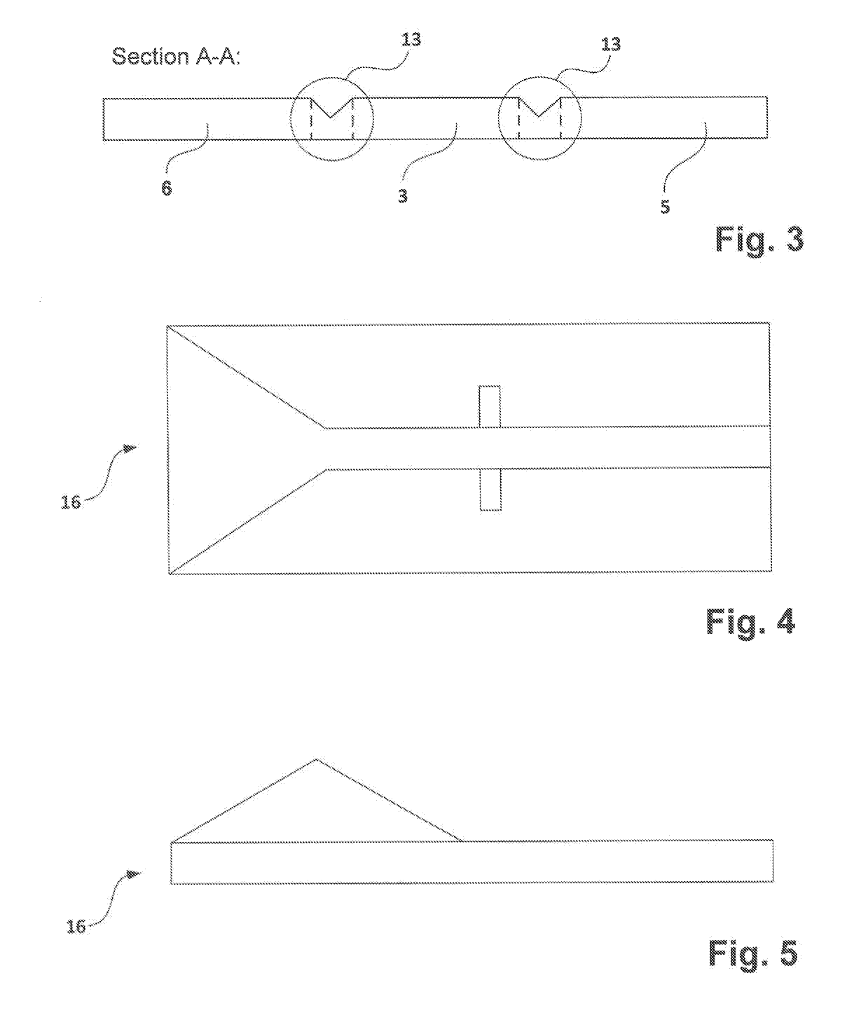

FIG. 3 a cross section taken on the cutting plane A-A of FIG. 1,

FIG. 4 a plan view of a spacing apparatus,

FIG. 5 a side view of the spacing apparatus of FIG. 4,

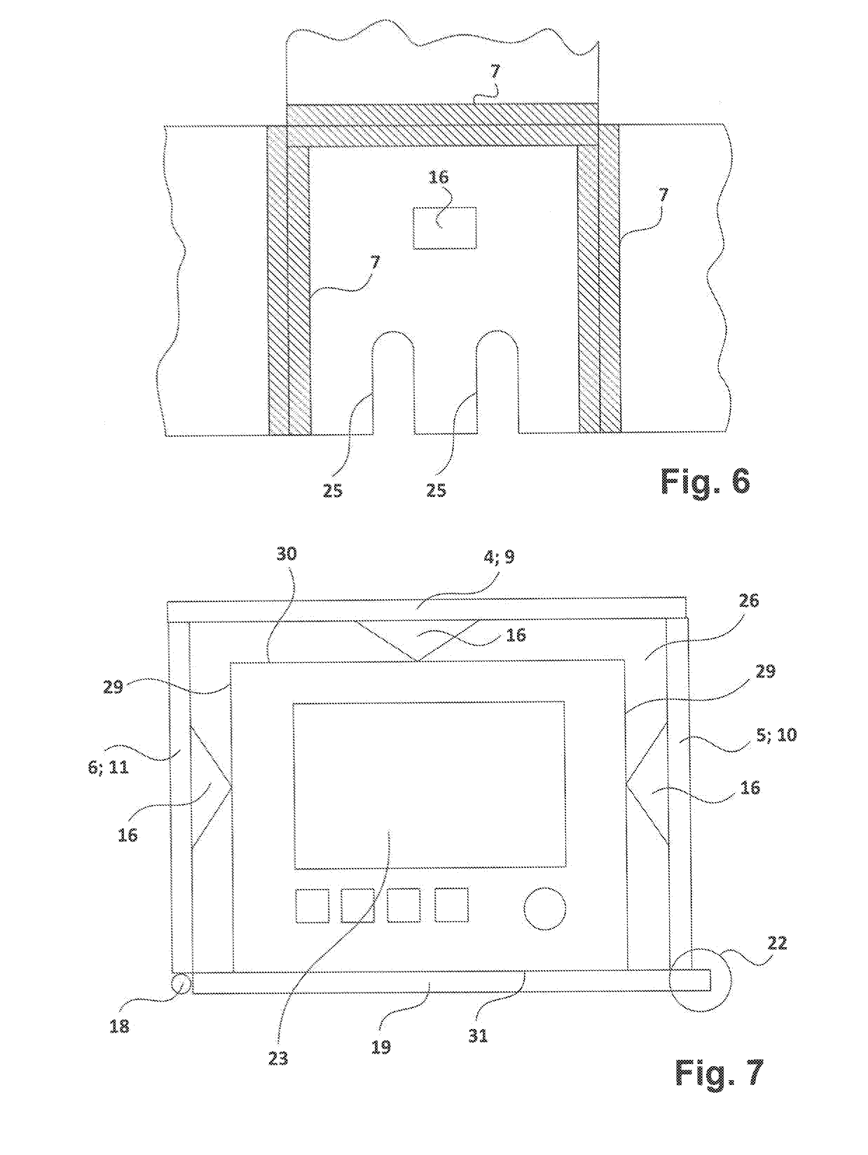

FIG. 6 a rear view of a roof segment,

FIG. 7 a front view of the system,

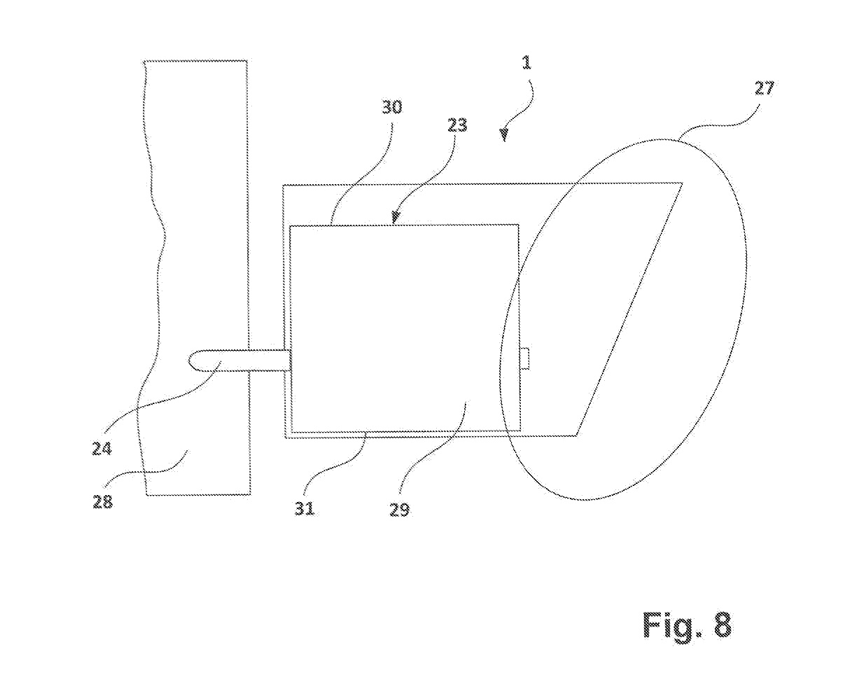

FIG. 8 a side view of the system of FIG. 7.

FIG. 1 shows a plan view of an embodiment of the collapsible, protective apparatus 1 of the invention in the planar, spread mode embodied in the form of an element 2. The collapsible, protective apparatus 1 of the invention is preferably injection molded or cast of synthetic material, e.g. plastic, essentially in a planar, spread mode and is composed of a plurality of segments 3, 4, 5, 6, which are interconnected by way of bendable transition regions 7. Thus, the protective apparatus 1 includes a roof segment 4, a rear wall segment 3 as well as two side wall segments 5, 6, which, after transport and storage, can be bent and/or folded and/or turned and/or swung at the bendable transition regions 7 to form a three-dimensional structure.

In the simplest case, the protective apparatus 1 can be composed of a maximum of two segments 3, 4, 5, 6, which are connected by way of one transition region 7, wherein these two segments are preferably a rear wall segment 3 and a roof segment 4.

The manufacturing technique, respectively manufacturing method, of plastic injection molding, or casting, permits the forming of complex shapes in all directions. Thus, especially, hinges and, moreover, also structures, which have a complex three-dimensional shape, can be formed. Thus, especially, snap fit mechanisms 14 and clip mechanisms 21 as well as counterpart means 15, 20 for engaging with, or being clipped by, these can be mentioned. Fundamentally, there are a large number of suitable snap fit mechanisms 14 and clip mechanisms 21 as well as counterpart means 15, 20 for engaging with, or being clipped by, these available from the state of the art.

The protective apparatus 1 of FIG. 1 includes on each side wall segment 5, 6 such a means 15 for engaging, which, after the bending/folding/turning/swinging of the roof segment 4 and the two side wall segments 5, 6 into a three-dimensional structure, engages with the therefor provided, snap fit mechanism 14 on the roof segment 4. In this way, an especially stable, protective apparatus 1 can be implemented.

Shown in FIG. 1 are, furthermore, four spacing apparatuses 16, which are preferably located in the middle of the respective segments 3, 4, 5, 6 and can be set up from the planar, spread mode and remain standing stably in this set up mode. In this way, a stable, wind resistant support of the protective apparatus 1 for the object to be protected can be achieved.

With help of plastic injection molding, or casting, it is likewise possible to implement the spacing apparatuses 16 in such a manner that they are in the particular segment 3, 4, 5, 6 and, thus, require no additional space, or greater volume.

It should be noted here that it is not absolutely required that the protective apparatus 1 has four spacing apparatuses 16, but, instead, it is, in principle, likewise an option that, for example, only one spacing apparatus 16 is provided, on the roof segment 4. In this case, with the assistance of this one spacing apparatus 16 and the latch 19, the protective apparatus 1 is so emplaced on the object to be protected that an air gap 26 forms around the two side regions 29 and the top 30 of the housing of the object. This air gap 26 provides for an unhindered outflow of heat, which can, in given cases, be given off by the object to be protected.

Further shown in FIG. 1 is a latch 19, which is attached via a flexible joint 18 to one of the two side wall segments 5, 6 of the collapsible, protective apparatus 1. Latch 19 includes, in such case, a means 20 for releasable clipping, which clips to the clip counterpart 21 attached to the other side wall segment 5, 6. Clip counterpart 21 and the means 20 for releasable clipping are, in the same manner as the flexible joint 18, preferably likewise implemented by means of plastic injection molding technology or casting technology. The state of the art discloses a wide variety of procedures that can be used for this.

The so embodied latch 19 has essentially two functions. On the one hand, in the clipped state, it assures that the collapsible, protective apparatus 1 stays with the object to be protected, and, on the other hand, it cooperates with the spacing apparatuses 16 to assure that the object to be protected is held as centrally as possible in the protective apparatus 1.

Furthermore, the clip counterpart 21 and the means 20 for releasable clipping are embodied in such a manner that the connection, after the closing, respectively clipping, can be manually later released. Serving for this is the gripping element 22 shown in FIG. 1. This can, in the simplest mode, be so embodied that it is only a lengthening of the latch 19, i.e. the part, which protrudes beyond the side element 5, 6, to which the latch 19 is clipped.

Further shown schematically in FIG. 1 are two securement mechanisms 17, which will not be explored here, but, instead, in the description of FIG. 6.

FIG. 2 shows a plan view of an embodiment of the collapsible, protective apparatus 1 of the invention embodied of a plurality of individual segments 8, 9, 10, 11, wherein the individual segments 8, 9, 10, 11 are connected with one another with the assistance of securing means 12.

The collapsible, protective apparatus 1 shown in FIG. 2 is composed of a roof segment 9, and a rear wall segment 8, as well as two side wall segments 10, 11, all of which have securement means 12, which serve for engaging and/or snap fitting and/or interlocking of the segments and secure them against unintentional separation from one another.

In the simplest case, the protective apparatus 1 can be composed of a maximum of two individual segments 8, 9, 10, 11, which are connected with, in each case, at least one securement means 12, wherein these two individual segments 8, 9, 10, 11 are preferably a rear wall segment 8 and a roof segment 9.

The securement means 12 are embodied in such a manner that, in each case, two securement means 12 can be connected with one another.

At this position, it should be noted that it is not, as shown in FIG. 2, absolutely required that the individual segment 8, 9, 10, 11 have, as a whole, twenty securement means 12 for interlocking the individual segment 8, 9, 10, 11 into a block-like structure. Other options include, for example, just ten securement means 12, so that at each joint, thus between roof segment 9 and the two side wall segments 10, 11, as well as between the side wall segments 10, 11 and the rear wall segment 8 and between the rear wall segment 8 and the roof segment 9, in each case, one securement means 12 is provided per joint. In principle, in given cases, also less than ten, for example, six securement means 12 provide an option. The reducing of the securement means 12 can, however, reduce the stability of the protective apparatus 1 in its three-dimensional structure. Therefore, one should strive to find an optimum of stability and number of securement means 12.

The securement means 12 can likewise be produced in plastic injection molding technology, or casting technology, and can be implemented from a plurality of options from the state of the art.

The collapsible, protective apparatus 1 shown in FIG. 2 has, relative to the spacing apparatus 16, the latch 19, the grip element 22, the clip counterpart 21, the means 20 for releasable clipping of the latch 19 and the flexible joint 18, as well as the securement mechanisms 17, the same properties and functions as already described in FIG. 1, or as will be described for FIG. 6.

FIG. 3 shows a cross section (A-A) through the collapsible, protective apparatus 1 of FIG. 1. In such case, shown in the section are the two side wall segments 5, 6 and the bendable transition regions 7 as well as the rear wall segment 3, wherein the transition regions 7 are embodied as so called film hinges, respectively folding hinges.

FIG. 4 shows a plan view of a spacing apparatus 16 in the planar, spread mode. This spacing apparatus 16 can be moved between its set up mode and its planar mode, as required, and is embodied in such a manner that it can remain standing stably in its set up mode, such that an unintended collapse, or release, is prevented.

In principle, the spacing apparatus 16 can be implemented building on the segment 3, 4, 5, 6 or, however, also, in the segment 3, 4, 5, 6. Integration of the spacing apparatus 16 in the segment 3, 4, 5, 6 offers the advantage that the transport volume can be kept small. For this, plastic injection molding technology provides corresponding means, respectively options.

FIG. 5 shows a side view of the spacing apparatus 16 of FIG. 4, wherein the spacing apparatus 16 is so set up that, in the case of need, it also provides stable and wind resistant support relative to the object to be protected.

FIG. 6 shows a rear view of the rear wall segment 8, wherein the securement mechanisms 17, in such case, are embodied as cutouts 25. Concerning the operation of the securement mechanisms 17, respectively cutouts 25, this will be discussed below in the description of FIG. 8.

FIG. 7 shows a front view of the system composed of a field device 23 and the collapsible, protective apparatus 1. The protective apparatus 1 is, in such case, capped, or pushed, down over the field device 23 and, with the assistance of the spacing apparatuses 16 and the latch 19, emplaced, or positioned in such a manner on or over the field device 23 that an air gap 26 forms between the field device 23 and the protective apparatus 1. This air gap 26 serves to accommodate, or to lead away, typically occurring field device heat, which is given off via the side regions 29 as well as the top of the field device 23. Of course, the protective apparatus 1 is ideally so emplaced on or over the field device 23 with the assistance of the spacing apparatuses 16 and the latch 19 that the air gap 26 forms around the two side regions 29 as well as the top 30 of the field device 23 and not only, for example, on one of the two side regions 29 or only on the top 30 of the field device.

Also shown in FIG. 7 is the gripping element 22, which serves for intentional releasing of the latch 19, or of the means 20 for clipping, from the clip counterpart 21. In the simplest case, the gripping element 22 is implemented in such a manner that it is simply a lengthening of the latch 19. Fundamentally, any number of forms of grip elements known from the state of the art can be used as grip element 22

FIG. 8 shows a side view of the system of FIG. 7, wherein the field device 23 is affixed at the location 28 of installation with at least one securement element 24, preferably a screw. The at least one cutout 25 is implemented in such a manner that the rear wall segment 3; 8 of the protective apparatus 1 can be slid, or pushed, down onto the at least one securement element 24 and, in this way, the protective apparatus 1 becomes affixed in such a manner that it can only be withdrawn by pulling it upwards.

Also shown in FIG. 8 is the protrusion 27, which is formed from the side wall segments 5, 6; 10, 11 and the roof segment 4; 9. This protrusion 27 is embodied in such a manner that it produces a greatest possible shade formation and, thus, also enables the user, or operator, in the presence of strong solar radiation, to read the display of the field device 23.

### LIST OF REFERENCE CHARACTERS

1 collapsible, protective apparatus
2 element
3 rear wall segment
4 roof segment
5 first side wall segment
6 second side wall segment
7 transition region
8 rear wall segment
9 roof segment
10 first side wall segment
11 second side wall segment
12 securement means
13 folding hinge
14 snap fit mechanism
15 first means for engaging the snap fit mechanism
16 spacing apparatus
17 securement mechanism
18 flexible joint
19 latch
20 second means for releasable clipping to the clip counterpart
21 clip counterpart
22 gripping element for releasing the latch
23 field device
24 securement element
25 cutout
26 air gap
27 protrusion
28 location of installation
29 side regions of the housing of the field device
30 top of the housing of the field device
31 underside of the housing of the field device

1-15. (canceled)

16. A collapsible protective apparatus for protecting an object against weather related influences, comprising:
an element having a plurality of interconnected segments, including at least one rear wall segment, a roof segment, a first side wall segment and a second side wall segment, wherein:
said segments are connected to one another via at least three bendable transition regions;
said transition regions are located between said roof segment and said rear wall segment and between said first side wall segment and said rear wall segment and between said second side wall segment and said rear wall segment; and
the individual segments can be formed from a planar, spread mode with the assistance of said transition regions into a three-dimensional structure.

17. A collapsible protective apparatus for protecting an object against weather related influences, comprising:
a plurality of individual segments, including at least one rear wall segment, a roof segment, a first side wall segment and a second side wall segment, wherein:
said rear wall segment, said roof segment, said first side wall segment and said second side wall segment have securement means; and
the individual segments can be connected from a planar, spread mode by shape interlocking of the securement means into a three-dimensional structure.

18. The collapsible protective apparatus as claimed in claim 16, wherein:
at least one of said segments has, in each case, at least one spacing apparatus; and
said at least one spacing apparatus is arranged in such a manner on the, in each case, corresponding segment that it can be set up from the plane of said segment.

19. The protective apparatus as claimed in claim 16, wherein:
said transition regions are implemented as hinges.

20. The protective apparatus as claimed in claim 16, wherein:
said roof segment has at least one snap fit mechanism; and
said first side segment and said second side segment, in each case, there is provided at least a first means for engaging with said snap fit mechanism of said roof segment.

21. The protective apparatus as claimed in claim 17, wherein:
said securement means is embodied in such a manner that said roof segment, said rear wall segment, said first side wall segment and said second side wall segment can be connected to form the three-dimensional structure.

22. The protective apparatus as claimed in claim 16, wherein:
said rear wall segment has at least one securement mechanism, with the assistance of which the collapsible, protective apparatus is secured to the object to be protected.

23. The protective apparatus as claimed in claim 16, wherein:
one of said two side segments has a latch connected via a flexible joint; and
a second means is provided on said latch for releasable clipping to said other side segment.

24. The protective apparatus as claimed in claim 23, wherein:
said side segment, to which said latch is clipped, has a clip counterpart, which receives said second means for releasable clipping of said latch.

25. The protective apparatus as claimed in claim 24, wherein:
said latch is so embodied that, in the clipped state, it protrudes beyond the side, to which it is clipped, in such a manner that a gripping element forms for releasing said latch.

26. A system comprising:
at least one protective apparatus, as claimed in claim 16, and at least one object to be protected, wherein:
said object to be protected is a field device of automation technology; and
the collapsible, protective apparatus is placed on the field device of automation technology.

27. The system as claimed in claim 26, wherein:
the field device is affixed at a location of installation via at least one securement element;
said securement mechanism of the protective apparatus has at least one cutout;
said cutout is located on said rear wall segment in such a manner that, in the case of placing the protective apparatus on the field device, said cutout receives said at least one securement element of the field device; and
the collapsible, protective apparatus is affixed to the field device in such a manner that an unintended slipping off is prevented.

28. The system as claimed in claim 26, wherein:
said latch of the collapsible, protective apparatus tightens, with the assistance of the underside of the housing of the field device, in such a manner that removal of the protective apparatus without a preceding releasing of said clip counterpart is prevented.

29. The system as claimed in claim 26, wherein:
said at least one spacing apparatus is embodied in such a manner that the collapsible, protective apparatus is so positionable on the field device that an air gap forms between said side segments as well as said roof segment of the protective apparatus and said side regions as well as the top of the housing of the field device.

30. The system as claimed in claim 26, wherein:
said roof segment and said two side segments are so embodied that said roof segment and said two side segments protrude frontally over the field device; and
said side segments terminate essentially flushly with said roof segment and, thus, form a protrusion.
